(19) United States
(12) Patent Application Publication
(10) Pub. No.: US 2025/0279326 A1
(43) Pub. Date: Sep. 4, 2025

(54) SEMICONDUCTOR ELEMENT, SEMICONDUCTOR DEVICE, AND METHOD FOR MANUFACTURING SEMICONDUCTOR ELEMENT

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Toru SHONO, Himeji Hyogo (JP); Koji ONISHI, Ibo Hyogo (JP); Naoya NISHIJIMA, Ibo Hyogo (JP)

(21) Appl. No.: 18/830,492

(22) Filed: Sep. 10, 2024

(30) Foreign Application Priority Data
Mar. 4, 2024 (JP) 2024-032278

(51) Int. Cl. H01L 23/31; H01L 21/78; H01L 23/495

(52) U.S. Cl. CPC H01L 23/3185; H01L 21/78; H01L 23/495

(57) ABSTRACT

A semiconductor element includes: a semiconductor layer having a front surface on which a circuit pattern is formed; an electrode layer disposed on a back surface of the semiconductor layer; and a covering layer covering a back surface of the electrode layer, and a side surface of the semiconductor layer and the electrode layer.

### CROSS-REFERENCE TO RELATED APPLICATIONS

This application is based upon and claims the benefit of priority from Japanese Patent Application No. 2024-032278, filed on Mar. 4, 2024; the entire contents of which are incorporated herein by reference.

### FIELD Embodiments of the invention relate to a semiconductor element, a semiconductor device, and a method for manufacturing a semiconductor element.

### BACKGROUND

Examples of semiconductor devices manufactured by using a lead frame include MOSFETs (Metal Oxide Semiconductor Field Effect Transistors), IGBTs (Insulated Gate Bipolar Transistors), and FRDs (Fast Recovery Diodes). In such a semiconductor device, a semiconductor element is mounted on the lead frame.

In the process of manufacturing such a semiconductor element, a burr may be formed on the side surface or the back surface of the semiconductor element during the process of singulation from the wafer. Leaving such a burr formed on the semiconductor element may involve a risk of decreased quality of the semiconductor device.

### BRIEF DESCRIPTION OF THE DRAWINGS

FIG. 1 is a cross-sectional view of a semiconductor device according to an embodiment;

FIG. 2 is a cross-sectional view of a semiconductor element according to the embodiment;

FIG. 3A is a diagram illustrating a state when the semiconductor element according to the embodiment is heated;

FIG. 3B is a diagram illustrating a state when the semiconductor element according to the embodiment is cooled;

FIG. 4 is a flowchart illustrating a flow of a method for manufacturing the semiconductor element according to the embodiment;

FIG. 5A is a diagram illustrating an arrangement process in the method for manufacturing the semiconductor element;

FIG. 5B is a cross-sectional view taken along line V-V in a region R in FIG. 5A;

FIG. 6A is a diagram illustrating a covering process in the method for manufacturing the semiconductor element;

FIG. 6B is a cross-sectional view taken along line VI-VI in the region R in FIG. 6A;

FIG. 7A is a diagram illustrating a second dicing process in the method for manufacturing the semiconductor element;

FIG. 7B is a cross-sectional view taken along line VII-VII in the region R in FIG. 7A;

FIG. 8 is a cross-sectional view of a semiconductor element according to modification 1; and

FIG. 9 is a cross-sectional view of a semiconductor element according to modification 2.

### DETAILED DESCRIPTION

A semiconductor element according to an embodiment includes: a semiconductor layer having a front surface on which a circuit pattern is formed; an electrode layer disposed on a back surface of the semiconductor layer; and a covering layer covering a back surface of the electrode layer, and a side surface of the semiconductor layer and the electrode layer.

Hereinafter, embodiments of the invention will be described with reference to the drawings. The embodiments are not intended to limit the invention. The drawings are schematic or conceptual and, for example, the proportions of respective parts are not necessarily the same as the actual proportions. In the specification and drawings, components similar to those described in regard to a drawing thereinabove are marked with like reference numerals, and a detailed description is omitted as appropriate.

Terms and the like, such as “parallel” and “same”, used in the specification to specify shapes or geometrical conditions and the degrees thereof are not limited to their strict meanings and are construed as including the extent to which similar functions can be expected.

### Embodiments

### 1. Semiconductor Device 1

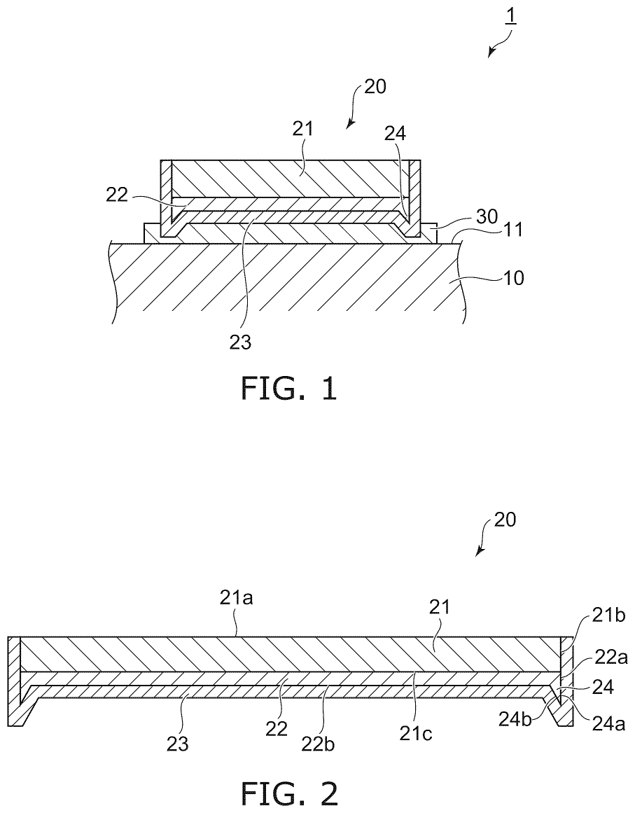

A semiconductor device 1 according to an embodiment will be described with reference to FIG. 1 and FIG. 2. FIG. 1 is a cross-sectional view of the semiconductor device according to this embodiment. FIG. 2 is a cross-sectional view of a semiconductor element according to this embodiment.

As shown in FIG. 1 and FIG. 2, the semiconductor device 1 according to this embodiment includes a lead frame 10, a semiconductor element 20, and a bonding material 30.

The lead frame 10 has a frame main surface 11. The frame main surface 11 serves as a region (mount region) in which the semiconductor element 20 is mounted with the bonding material 30 therebetween. Note that the lead frame 10 may have, for example, a lead not illustrated.

As shown in FIG. 2, the semiconductor element 20 includes a semiconductor layer 21 having a front surface 21a on which a circuit pattern is formed, an electrode layer 22 provided on a back surface 21c of the semiconductor layer 21, and a covering layer 23 covering a back surface 22b of the electrode layer 22, a side surface 22a of the electrode layer 22, and a side surface 21b of the semiconductor layer 21.

In the semiconductor device 1, the electrode layer 22 of the semiconductor element 20 is bonded to the lead frame 10 with the bonding material 30 therebetween. In one example, the semiconductor element 20 may have a square shape in plan view or a rectangular shape in plan view.

In this embodiment, the semiconductor element 20 is an IGBT. Note that the semiconductor element 20 is not limited to a specific type and may be, for example, a MOSFET or an FRD.

The semiconductor layer 21 includes a p-type semiconductor region and an n-type semiconductor region formed in accordance with the type of the semiconductor element 20. The semiconductor layer 21 is a semiconductor layer made of a semiconductor containing, for example, any of silicon (Si), silicon carbide (SiC), and gallium nitride (GaN). When silicon is used as the material of the semiconductor layer 21, for example, arsenic, phosphorus, or antimony is used as the n-type impurity and, for example, boron is used as the p-type impurity. Note that the semiconductor layer 21 may be an epitaxial layer, may be a semiconductor substrate obtained by singulating a wafer, or may be formed of an epitaxial layer and a semiconductor substrate.

In this embodiment, the electrode layer 22 functions as the collector electrode of the IGBT. In this case, a surface, of the semiconductor layer 21, being in contact with the electrode layer 22 functions as the p-type semiconductor region.

With the bonding material 30, the semiconductor element 20 is bonded to the lead frame 10. The bonding material 30 can be any of various materials, such as solder or conductive paste. Although the bonding material 30 spreads laterally beyond the semiconductor element 20 in FIG. 1, the bonding material 30 is not limited to this and may have a width the same as that of the semiconductor element 20.

The electrode layer 22 will now be described in detail. As shown in FIG. 1 and FIG. 2, a burr (projection) 24 is formed on at least one of the side surface 22a and the back surface 22b of the electrode layer 22. In one example, the burr 24 is formed around the back surface 22b.

As shown in FIG. 2, an outer side surface 24a of the burr 24 is flush with the side surface 21b of the semiconductor layer 21 in this embodiment. In other words, the outer side surface 24a and the side surface 21b are positioned on the same plane. More specifically, the side surface 22a of the electrode layer 22 includes the outer side surface 24a of the burr 24, and the side surface 22a is flush with the side surface 21b of the semiconductor layer 21. Meanwhile, an inner side surface 24b of the burr 24 intersects with the outer side surface 24a at an acute angle and extends further inward (toward the center of the back surface 22b) with distance from the tip. More specifically, the lateral length of the burr 24 increases with distance from the tip of the burr 24 toward the back surface 22b. The burr 24 has such a form because the burr 24 is formed upon dicing as described below.

The covering layer 23 covers the back surface 22b of the electrode layer 22, the side surface 21b of the semiconductor layer 21, and the side surface 22a of the electrode layer 22. That is, the covering layer 23 covers the burr 24. The covering layer 23 contains a metal material different from that of the electrode layer 22. When the material of the electrode layer 22 is referred to as a first metal material and the material of the covering layer 23 is referred to as a second metal material, the Young's modulus of the second metal material is higher than the Young's modulus of the first metal material. The linear expansion coefficient of metal tends to be lower as the Young's modulus thereof is higher, and the linear expansion coefficient of the second metal material is lower than the linear expansion coefficient of the first metal material.

The first metal material contains, for example, aluminum, silver, or both of them. In one example, the first metal material is mainly aluminum in this embodiment. The second metal material contains, for example, nickel, copper, or both of them. In one example, the second metal material is mainly nickel in this embodiment.

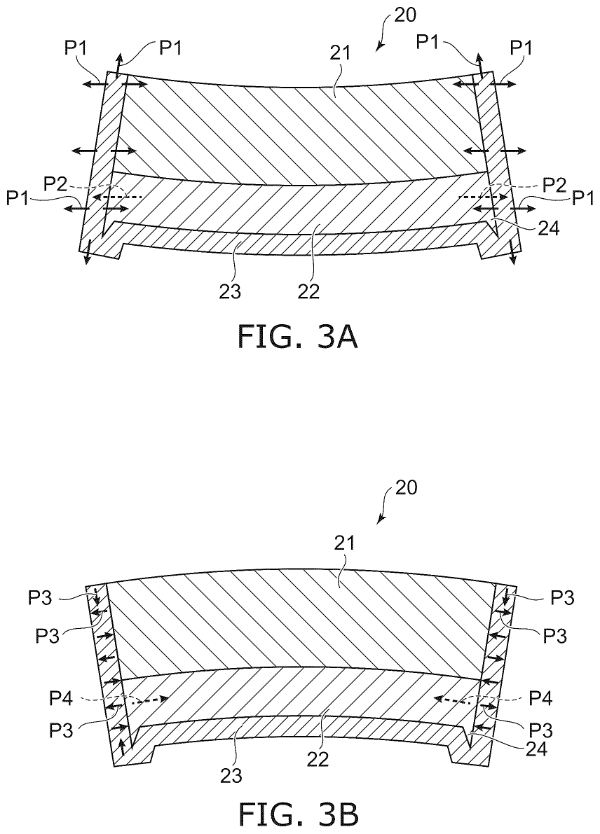

Thermal expansion of the semiconductor element 20 will be described with reference to FIGS. 3A and 3B. FIG. 3A is a diagram illustrating a state when the semiconductor element 20 is heated. As shown in FIG. 3A, when the semiconductor element 20 is heated, the electrode layer 22 and the covering layer 23 are subjected to an expansion force. Here, a metal having a higher Young's modulus (or a lower linear expansion coefficient) than that of the electrode layer 22 is used as the covering layer 23, and therefore, the thermal expansion coefficient of the covering layer 23 is lower than the thermal expansion coefficient of the electrode layer 22. Therefore, a strain P1 due to expansion of the covering layer 23 resulting from heating is smaller than a strain P2 due to expansion of the electrode layer 22. As a result, expansion that may normally occur in the electrode layer 22 is restrained or reduced by the covering layer 23.

FIG. 3B is a diagram illustrating a state when the semiconductor element according to this embodiment is cooled. As shown in FIG. 3B, when the semiconductor element 20 is cooled, the electrode layer 22 and the covering layer 23 are subjected to a contraction force. Here, a metal having a higher Young's modulus (or a lower linear expansion coefficient) than that of the electrode layer 22 is used as the covering layer 23, and therefore, the thermal expansion coefficient of the covering layer 23 is lower than the thermal expansion coefficient of the electrode layer 22. Therefore, a strain P3 due to contraction of the covering layer 23 resulting from cooling is smaller than a strain P4 due to contraction of the electrode layer 22. As a result, contraction that may normally occur in the electrode layer 22 is restrained or reduced by the covering layer 23.

### 2. Method for Manufacturing

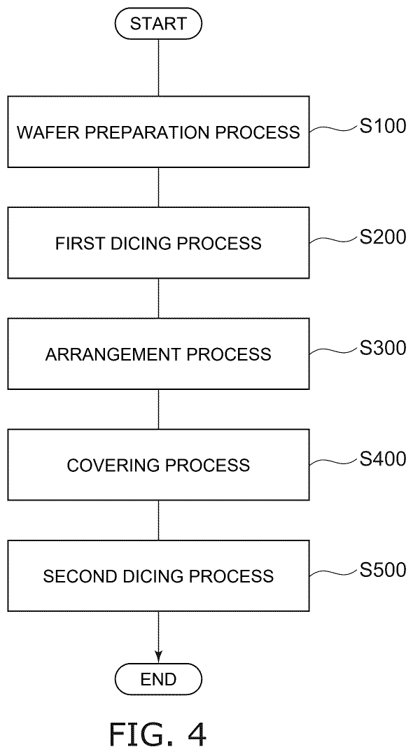

A method for manufacturing the semiconductor element 20 according to this embodiment will be described with reference to FIG. 4 to FIG. 7B. FIG. 4 is a flowchart illustrating a flow of the method for manufacturing the semiconductor element 20. As shown in FIG. 4, the method for manufacturing the semiconductor element 20 includes a wafer preparation process (S100), a first dicing process (S200), an arrangement process (S300), a covering process (S400), and a second dicing process (S500).

In the wafer preparation process (S100), a wafer having a front surface on which a circuit pattern is formed and a back surface on which an electrode layer is provided is prepared. In one example, the wafer may be prepared by performing processes including a mask manufacturing process, a wafer manufacturing process, and a pre-process (circuit pattern formation and electrode formation) in a semiconductor manufacturing process.

In the first dicing process (S200), the wafer prepared in the wafer preparation process (S100) is diced and singulated into a plurality of semiconductor elements 40. As a result of the first dicing process (S200), the burr 24 is formed on at least one of the side surface and the back surface of the electrode layer 22 of each semiconductor element 40.

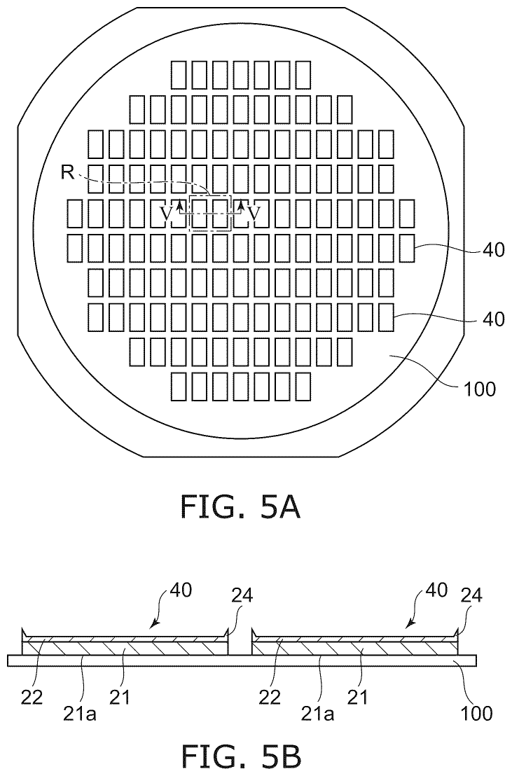

In the arrangement process (S300), the plurality of semiconductor elements 40 are arranged in a planar form with the back surfaces facing upward and with gaps therebetween. Specifically, as shown in FIG. 5A, the plurality of semiconductor elements 40 are arranged on a dicing tape 100 in a planar form.

FIG. 5B is a cross-sectional view taken along line V-V in a region R in FIG. 5A. As shown in FIG. 5B, as a result of the arrangement process (S300), the plurality of semiconductor elements 40 are arranged in a planar form with the electrode layers 22 facing upward.

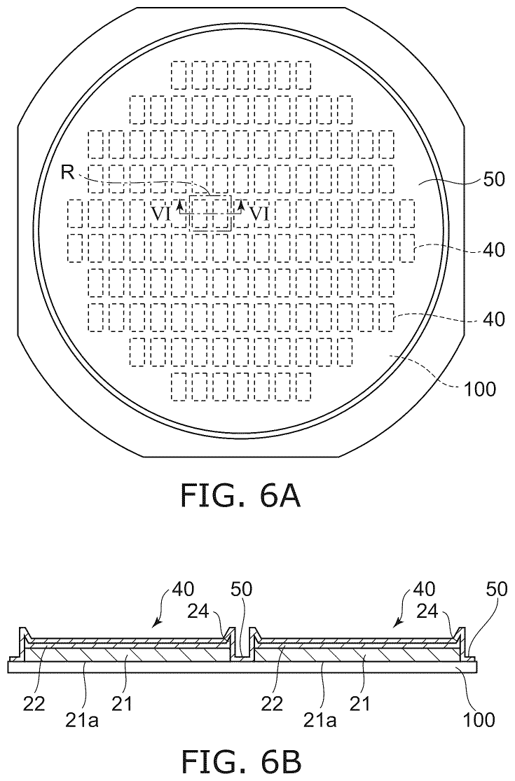

In the covering process (S400), the back surfaces of the plurality of semiconductor elements 40 and each gap formed between corresponding ones of the plurality of semiconductor elements 40 are covered with a covering material 50. Specifically, as shown in FIG. 6A, the plurality of semiconductor elements 40 arranged on the dicing tape 100 in a planar form are entirely covered with the covering material 50. The covering material 50 is the second metal material and contains, for example, nickel, copper, or both of them.

FIG. 6B is a cross-sectional view taken along line VI-VI in FIG. 6A. As shown in FIG. 6B, as a result of the covering process (S400), the burr 24 formed on at least one of the side surface and the back surface of the electrode layer 22 of each semiconductor element 40 is also covered with the covering material 50.

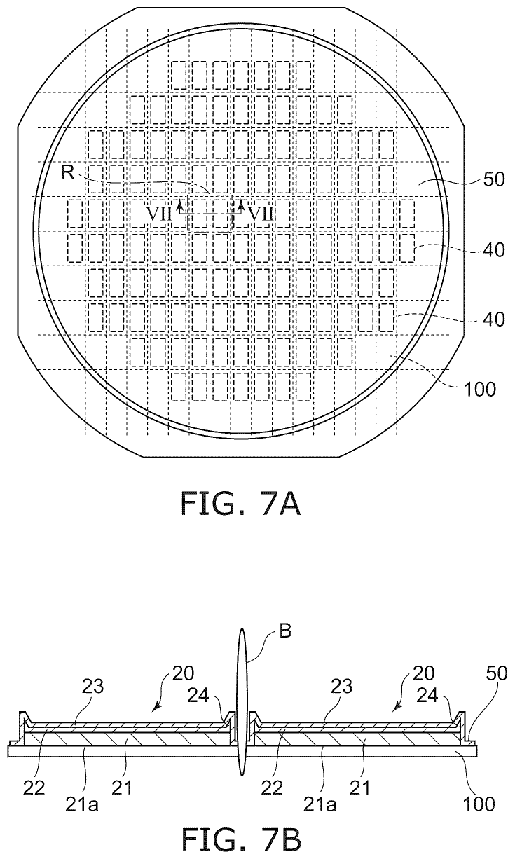

In the second dicing process (S500), dicing is performed by cutting along the gaps between the plurality of semiconductor elements 40. Specifically, as shown in FIG. 7A, cutting from above the covering material 50 is performed along the gaps between the plurality of semiconductor elements 40 (which are illustrated in dotted lines in FIG. 7A). FIG. 7B is a cross-sectional view taken along line VII-VII in FIG. 7A. As shown in FIG. 7B, as a result of the second dicing process (S500) with a cutter B, the plurality of semiconductor elements 40 covered with the covering material 50 are singulated, and the semiconductor elements 20 each including the covering layer 23 on the back surface can be obtained.

### 3. Summation

As described above, the semiconductor element 20 according to this embodiment includes: the semiconductor layer 21 having a front surface on which a circuit pattern is formed; the electrode layer 22 disposed on the back surface of the semiconductor layer 21; and the covering layer 23 covering the back surface of the electrode layer 22, and the side surface of the semiconductor layer 21 and the electrode layer 22. With such a configuration, a burr that may be formed on the side surface or the back surface of the semiconductor element 20 during the process of manufacturing the semiconductor element 20 can be covered with the covering layer 23, and a risk of decreased quality caused by the burr can be reduced. As described above, the influence of thermal expansion can be reduced, and therefore, a reduction in a warp can be expected upon die bonding of the semiconductor element 20 or mounting of the semiconductor element 20 as a semiconductor chip. Although a semiconductor device in which frame bonding is performed has been described in the above-described embodiment, the invention is not limited to this form, and the technical idea in the above-described embodiment may be applied to a semiconductor device including, for example, an LGA (Land Grid Array) package.

### 4. Modification 1

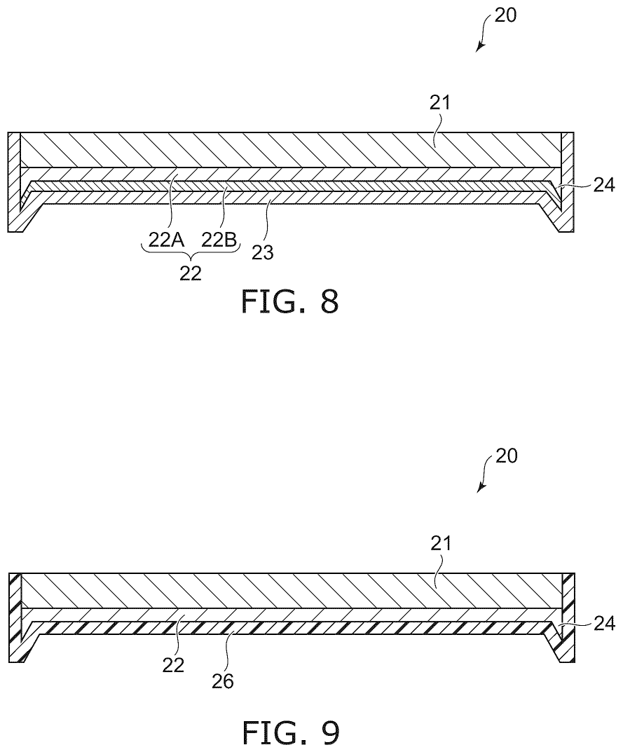

Modification 1 of the above-described embodiment will be described with reference to FIG. 8. In modification 1, the electrode layer 22 includes a first layer 22A containing a first metal material and a second layer 22B containing a second metal material different from the first metal material. In one example, as the first metal material, a metal, such as aluminum or silver, having a low Young's modulus and a high linear expansion coefficient may be used. As the second metal material, a metal, such as nickel or copper, having a high Young's modulus and a low linear expansion coefficient may be used. Accordingly, the technical idea of the disclosure is also applicable to an existing semiconductor element in which the electrode layer 22 is formed of a plurality of layers, and effects similar to those described in the above-described embodiment can be obtained.

### 5. Modification 2

Modification 2 of the above-described embodiment will be described with reference to FIG. 9. In modification 2, an insulating covering layer 26 containing an insulating material is formed instead of the covering layer 23 in the above-described embodiment. The insulating material contains, for example, a resin material. Specifically, as the resin material of the insulating covering layer 26, a granular epoxy resin composition for semiconductor encapsulation may be used. With such a configuration, effects similar to those described in the above-described embodiment can be obtained, and covering the electrode layer 22 with the insulating material can prevent conduction between the electrode layer 22 and a pad electrode (not illustrated) disposed on the front surface 21a of the semiconductor layer 21. Furthermore, an ionized substance that may be generated in the semiconductor device 1 can be prevented from interfering with the semiconductor layer 21 or the electrode layer 22.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The invention includes the following forms.

### Appendix 1

A semiconductor element including:
a semiconductor layer having a front surface on which a circuit pattern is formed;
an electrode layer disposed on a back surface of the semiconductor layer; and
a covering layer covering a back surface of the electrode layer, and a side surface of the semiconductor layer and the electrode layer.

### Appendix 2

The element according to appendix 1, in which
the electrode layer contains a first metal material, and
the covering layer contains a second metal material different from the first metal material.

### Appendix 3

The element according to appendix 2, in which the second metal material has a Young's modulus higher than a Young's modulus of the first metal material.

### Appendix 4

The element according to appendix 1, in which the electrode layer includes a first layer containing a first metal material, and a second layer containing a second metal material different from the first metal material.

### Appendix 5

The element according to appendix 1, in which the covering layer contains a resin material.

### Appendix 6

The element according to any one of appendixes 1 to 5, in which
a projection is formed on at least one of a side surface and the back surface of the electrode layer, and
the covering layer covers the projection.

### Appendix 7

A semiconductor device including:
a lead frame; and
a semiconductor element disposed on the lead frame,
the semiconductor element including
   a semiconductor layer having a front surface on which a circuit pattern is formed,
   an electrode layer disposed on a back surface of the semiconductor layer, and
   a covering layer covering a back surface of the electrode layer, and a side surface of the semiconductor layer and the electrode layer.

### Appendix 8

A method for manufacturing a semiconductor element, including:
dicing a wafer having a front surface on which a circuit pattern is formed and a back surface on which an electrode layer is provided, into a plurality of semiconductor elements;
arranging the plurality of semiconductor elements in a planar form with back surfaces thereof facing upward and with gaps therebetween;
covering the back surfaces and the gaps with a covering material; and
performing dicing by cutting along the gaps.

### Appendix 9

The method according to appendix 8, in which
a projection is formed on at least one of a side surface and the back surface of the electrode layer, and
the covering the back surfaces and the gaps with a covering material includes covering the projection with the covering material.

What is claimed is:

1. A semiconductor element comprising:
a semiconductor layer having a front surface on which a circuit pattern is formed;
an electrode layer disposed on a back surface of the semiconductor layer; and
a covering layer covering a back surface of the electrode layer, and a side surface of the semiconductor layer and the electrode layer.

2. The element according to claim 1, wherein
the electrode layer contains a first metal material, and
the covering layer contains a second metal material different from the first metal material.

3. The element according to claim 2, wherein the second metal material has a Young's modulus higher than a Young's modulus of the first metal material.

4. The element according to claim 1, wherein the electrode layer includes a first layer containing a first metal material, and a second layer containing a second metal material different from the first metal material.

5. The element according to claim 1, wherein the covering layer contains a resin material.

6. The element according to claim 1, wherein
a projection is formed on at least one of a side surface and the back surface of the electrode layer, and
the covering layer covers the projection.

7. A semiconductor device comprising:
a lead frame; and
a semiconductor element disposed on the lead frame,
the semiconductor element including
a semiconductor layer having a front surface on which a circuit pattern is formed,
an electrode layer disposed on a back surface of the semiconductor layer, and
a covering layer covering a back surface of the electrode layer, and a side surface of the semiconductor layer and the electrode layer.

8. A method for manufacturing a semiconductor element, comprising:
dicing a wafer having a front surface on which a circuit pattern is formed and a back surface on which an electrode layer is provided, into a plurality of semiconductor elements;
arranging the plurality of semiconductor elements in a planar form with back surfaces thereof facing upward and with gaps therebetween;
covering the back surfaces and the gaps with a covering material; and
performing dicing by cutting along the gaps.

9. The method according to claim 8, wherein
a projection is formed on at least one of a side surface and the back surface of the electrode layer, and
the covering the back surfaces and the gaps with a covering material includes covering the projection with the covering material.
